(19) United States
(12) Patent Application Publication
(10) Pub. No.: US 2025/0374428 A1
(43) Pub. Date: Dec. 4, 2025

(54) WIRING SUBSTRATE

(71) Applicant: Shinko Electric Industries Co., Ltd., Nagano-ken (JP)

(72) Inventor: Tomonobu Hashimoto, Nagano-shi (JP)

(21) Appl. No.: 19/214,091

(22) Filed: May 21, 2025

(30) Foreign Application Priority Data
May 30, 2024 (JP) 2024-087779

(51) Int. Cl. H05K 1/11

(52) U.S. Cl. CPC H05K 1/115; H05K 2201/083

(57) ABSTRACT

A wiring substrate includes a core layer including a first through hole, a magnetic resin filling the first through hole, a first wiring layer arranged on an upper surface of the magnetic resin, and a first wedge portion extending from the first wiring layer and wedged into the core layer. The first wiring layer includes a structure in which a first metal film, a first metal layer, a second metal film, and a second metal layer are sequentially stacked on the upper surface of the magnetic resin. The first wedge portion is formed continuously and integrally with the first metal film. The first wedge portion extends from the first metal film toward the core layer.

### CROSS-REFERENCE TO RELATED APPLICATIONS

This application is based upon and claims the benefit of priority from Japanese Patent Application No. 2024-087779, filed on May 30, 2024, the entire contents of which are incorporated herein by reference.

### BACKGROUND

### 1. Field

This disclosure relates to a wiring substrate and a method for manufacturing a wiring substrate.

### 2. Description of Related Art

An inductor built-in substrate is a type of a wiring substrate in which a magnetic resin body is embedded in a through hole formed in a core substrate (refer to Japanese Laid-Open Patent Publication No. 2019-220504). This type of wiring substrate includes a wiring layer stacked on the magnetic resin body.

### SUMMARY

In the typical wiring substrate, adhesion between the magnetic resin body and the wiring layer may not be satisfactory. Accordingly, the wiring layer may delaminate from the magnetic resin body, for example, during manufacture of the wiring substrate.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wiring substrate includes a core layer, a magnetic resin, a first wiring layer, and a first wedge portion. The core layer includes a first through hole. The magnetic resin fills the first through hole. The first wiring layer is arranged on an upper surface of the magnetic resin. The first wedge portion extends from the first wiring layer and is wedged into the core layer. The first wiring layer includes a structure in which a first metal film, a first metal layer, a second metal film, and a second metal layer are sequentially stacked on the upper surface of the magnetic resin. The first wedge portion is formed continuously and integrally with the first metal film. The first wedge portion extends from the first metal film toward the core layer.

Other features and aspects will be apparent from the following detailed description, the drawings, and the claims.

### BRIEF DESCRIPTION OF THE DRAWINGS

FIG. 1 is a schematic cross-sectional view of a wiring substrate in accordance with an embodiment.

FIG. 2 is a cross-sectional view enlarging part of the wiring substrate illustrated in FIG. 1.

FIGS. 3, 4, 5, 6, 7, 8, 9, 10, 11, 12, 13, 14, 15, and 16 are schematic cross-sectional views illustrating a method for manufacturing the wiring substrate illustrated in FIG. 1.

FIG. 17 is a schematic cross-sectional view illustrating a wiring substrate of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

A wiring substrate in accordance with an embodiment will now be described with reference to the drawings.

The accompanying drawings may not be drawn to scale, and the relative size, proportions, and depiction of elements may be exaggerated for clarity, illustration, or convenience. In the cross-sectional views, hatching lines may not be illustrated or may be replaced by shadings to facilitate understanding of the cross-sectional structures. Unless otherwise specified, a numerical range of “X1 to X2”, which is specified by a lower limit value X1 and an upper limit value X2, refers to a range that is greater than or equal to XI and less than or equal to X2.

### Overall Structure of Wiring Substrate 10

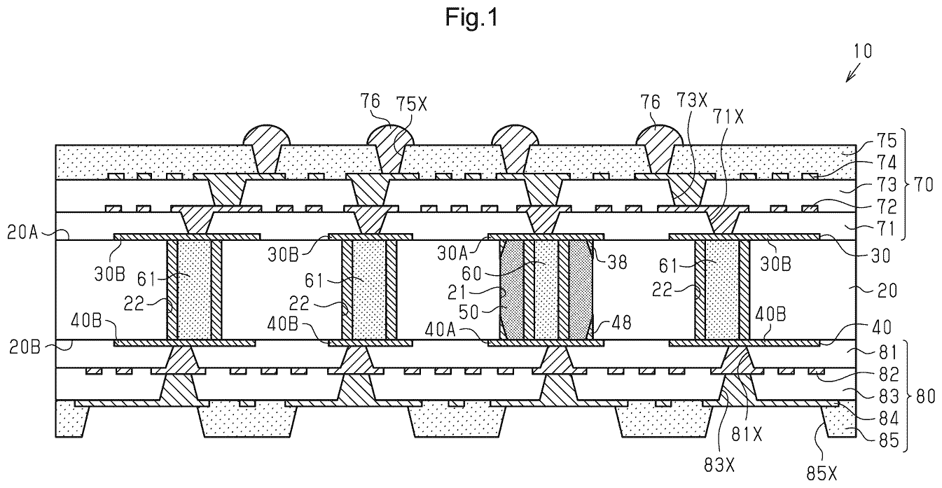

As illustrated in FIG. 1, a wiring substrate 10 includes a core layer 20, a wiring layer 30 arranged on an upper surface 20A of the core layer 20, a wiring layer 40 arranged on a lower surface 20B of the core layer 20, a magnetic resin 50, and filling resins 60 and 61. The wiring substrate 10 includes a wiring structure 70 arranged on the upper surface 20A of the core layer 20, and a wiring structure 80 arranged on the lower surface 20B of the core layer 20.

### Structure of Core Layer 20

The core layer 20 acts as, for example, a support body. The core layer 20 may be, for example, a glass epoxy substrate in which a glass cloth is impregnated with an insulating resin, such as an epoxy-based resin, a polyimide-based resin, or the like. The core layer 20 may be, for example, a substrate in which a woven or non-woven cloth of carbon fibers, aramid fibers, or the like is impregnated with an epoxy-based resin. The core layer 20 may have, for example, a thickness of approximately 400 μm to 1200 μm.

The core layer 20 includes through holes 21 and 22 extending through the core layer 20 in a thickness-wise direction. The through holes 21 and 22 may each have any planar shape and any size. The through holes 21 and 22 may each have, for example, a circular planar shape. The through hole 21 may have, for example, a diameter of approximately 350 μm to 450 μm. The through hole 22 has, for example, a smaller diameter than the through hole 21. The through hole 22 may have, for example, a diameter of approximately 150 μm to 250 μm. The through hole 21 is an example of a first through hole.

### Structure of Magnetic Resin 50

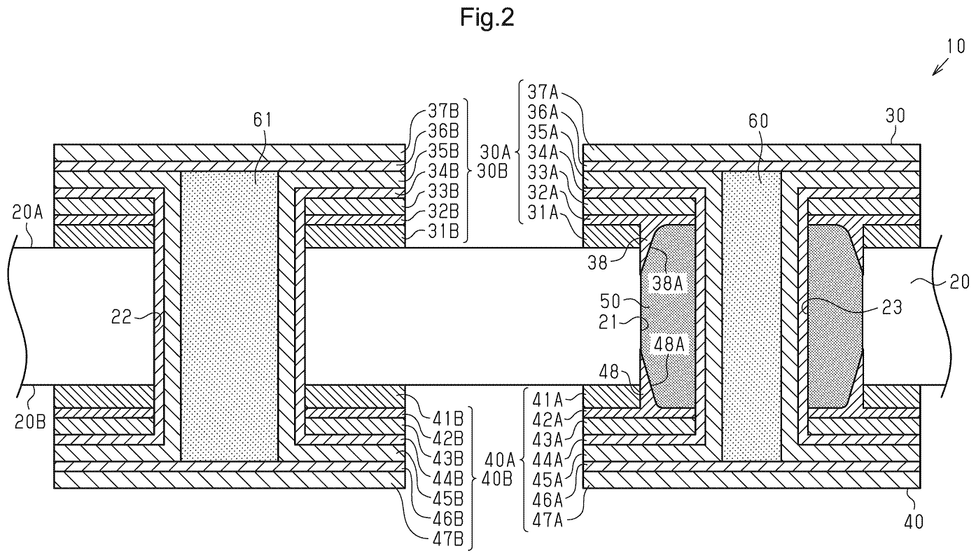

As illustrated in FIG. 2, the magnetic resin 50 is disposed inside the through hole 21. The magnetic resin 50 includes, for example, a resin material, such as an epoxy resin or the like, and magnetic particles dispersed in the resin material. Examples of the magnetic particles include a filler, such as iron, iron oxide, cobalt iron oxide, iron silicide, a magnetic alloy, a ferrite, or the like. In FIG. 2, the wiring structures 70 and 80 are not illustrated to simplify illustration.

The magnetic resin 50 includes a through hole 23 extending through the magnetic resin 50 in the thickness-wise direction. The through hole 23 may have any planar shape and any size. The through hole 23 may have, for example, a circular planar shape. The through hole 23 is, for example, concentric with the through hole 21. The through hole 23 may have, for example, a diameter of approximately 100 μm to 250 μm. The through hole 23 is an example of a second through hole.

The magnetic resin 50 has, for example, a greater thickness than the core layer 20. The magnetic resin 50 has an upper end, for example, projecting upward from the upper surface 20A of the core layer 20. The magnetic resin 50 has a lower end, for example, projecting downward from the lower surface 20B of the core layer 20.

### Structure of Wiring Layer 30

The wiring layer 30 includes, for example, pads 30A and 30B. The wiring layer 30 may include, for example, a wiring pattern connected to the pads 30A and 30B. The pads 30A and 30B may each have any planar shape and any size. The pads 30A and 30B may each have, for example, a circular planar shape.

### Structure of Wiring Layer 40

The wiring layer 40 includes, for example, pads 40A and 40B. The wiring layer 40 may include, for example, a wiring pattern connected to the pads 40A and 40B. The pads 40A and 40B may each have any planar shape and any size. The pads 40A and 40B may each have, for example, a circular planar shape.

### Structure of Pad 30A

The pad 30A is, for example, located on the magnetic resin 50. The pad 30A covers the upper end of the magnetic resin 50. The pad 30A covers, for example, the upper end of the magnetic resin 50 projecting upward from the upper surface 20A of the core layer 20. The pad 30A is located on the upper surface 20A of the core layer 20. The pad 30A (or wiring layer 30 including pad 30A) is an example of a first wiring layer.

The pad 30A includes, for example, a structure in which a metal foil 31A, a metal film 32A, a metal layer 33A, a metal film 34A, a metal layer 35A, a metal film 36A, and a metal layer 37A are sequentially stacked on the upper surface 20A of the core layer 20. The metal films 32A, 34A, and 36A are, for example, metal films formed by electroless plating, that is, the metal films are electroless plating films. The metal layers 33A, 35A, and 37A are, for example, metal layers formed by electrolytic plating, that is, the metal layers are electrolytic plating layers. The material of the metal foil 31A, the metal film 32A, the metal layer 33A, the metal film 34A, the metal layer 35A, the metal film 36A, and the metal layer 37A may be, for example, copper or a copper alloy. The metal film 32A is an example of a first metal film, and the metal layer 33A is an example of a first metal layer. The metal film 34A is an example of a second metal film, and the metal layer 35A is an example of a second metal layer. The metal film 36A is an example of a third metal film, and the metal layer 37A is an example of a third metal layer.

The metal foil 31A is stacked on the upper surface 20A of the core layer 20. The metal foil 31A surrounds, for example, a side surface of the upper end of the magnetic resin 50. The metal foil 31A has, for example, an annular planar shape. The metal foil 31A has, for example, an upper surface flush with the upper surface of the magnetic resin 50. In other words, the metal foil 31A has, for example, a thickness approximately equal to an amount of the magnetic resin 50 projected from the upper surface 20A of the core layer 20. The metal foil 31A may have, for example, a thickness of approximately 5 μm to 15 μm.

The metal film 32A is stacked on the upper surface of the metal foil 31A and the upper surface of the magnetic resin 50. The metal film 32A covers, for example, the entire upper surface of the metal foil 31A and the entire upper surface of the magnetic resin 50. The metal film 32A has, for example, an annular planar shape. The metal film 32A may have, for example, a thickness of approximately 1 μm to 3 μm.

The metal layer 33A is stacked on the upper surface of the metal film 32A. The metal layer 33A covers, for example, the entire upper surface of the metal film 32A. The metal layer 33A has, for example, an annular planar shape. The metal layer 33A may have, for example, a thickness of approximately 15 μm to 25 μm.

The through hole 23 extends through the magnetic resin 50, the metal film 32A, and the metal layer 33A in the thickness-wise direction.

The metal film 34A is stacked on the upper surface of the metal layer 33A. The metal film 34A covers the entire upper surface of the metal layer 33A. The metal film 34A is bent toward the wall surface of the through hole 23. The metal film 34A covers the wall surface of the through hole 23. The metal film 34A continuously covers the inner wall surface of the metal layer 33A, the inner wall surface of the metal film 32A, and the inner wall surface of the magnetic resin 50. The metal film 34A covers, for example, the entire inner wall surface of the metal layer 33A, the entire inner wall surface of the metal film 32A, and the entire inner wall surface of the magnetic resin 50. The metal film 34A may have, for example, a thickness of approximately 1 μm to 3 μm.

The metal layer 35A is stacked on the upper surface of the metal film 34A. The metal layer 35A covers the entire upper surface of the metal film 34A. The metal layer 35A is bent toward the wall surface of the through hole 23. The metal layer 35A covers the inner wall surface of the metal film 34A inside the through hole 23. The metal layer 35A covers, for example, the entire inner wall surface of the metal film 34A. The metal layer 35A may have, for example, a thickness of approximately 15 μm to 25 μm.

Inside the through hole 23, the metal film 34A is in direct contact with the wall surface of the through hole 23, and the metal layer 35A is stacked on the metal film 34A. The filling resin 60 fills the through hole 23 at the inner side of the metal layer 35A. The filling resin 60 may be, for example, an insulating resin (e.g., epoxy-based resin) containing a filler, such as silica or the like. The filling resin 60 has, for example, an upper surface flush with the upper surface of the metal layer 35A.

The metal film 36A is stacked on the upper surface of the metal layer 35A and the upper surface of the filling resin 60. The metal film 36A covers, for example, the entire upper surface of the metal layer 35A and the entire upper surface of the filling resin 60. The metal film 36A has, for example, a circular planar shape. The metal film 36A may have, for example, a thickness of approximately 1 μm to 3 μm.

The metal layer 37A is stacked on the upper surface of the metal film 36A. The metal layer 37A covers, for example, the entire upper surface of the metal film 36A. The metal layer 37A has, for example, a circular planar shape. The metal layer 37A may have, for example, a thickness of approximately 15 μm to 25 μm.

The pad 30A described above is, for example, greater in planar size than the through hole 23. The pad 30A is, for example, greater in planar size than the through hole 21. The pad 30A is, for example, greater in planar size than the magnetic resin 50. The pad 30A projects, for example, outward from the side surface of the magnetic resin 50.

The wiring substrate 10 includes a first wedge portion 38 extending from the pad 30A of the wiring layer 30 and wedged into the core layer 20. The first wedge portion 38 and the metal film 32A are the same metal film. The first wedge portion 38 and the metal film 32A are formed from the same material. The first wedge portion 38 and the metal film 32A are the same electroless plating film. The first wedge portion 38 is, for example, formed continuously and integrally with the metal film 32A. The first wedge portion 38 extends, for example, downward from the lower surface of the metal film 32A toward the core layer 20. The first wedge portion 38 extends, for example, through the metal foil 31A in the thickness-wise direction. The first wedge portion 38 has a distal end (here, lower end) wedged into the core layer 20. The first wedge portion 38 has, for example, a tapered shape that narrows toward the distal end. The first wedge portion 38 has, for example, a cross-sectional shape that is a right triangle as a whole. The first wedge portion 38 includes, for example, an inclined surface 38A. The inclined surface 38A faces, for example, the side surface of the magnetic resin 50. The inclined surface 38A is, for example, in contact with the side surface of the magnetic resin 50. The inclined surface 38A is in contact with the side surface of the magnetic resin 50, for example, over the entire length of the inclined surface 38A. The inclined surface 38A is, for example, inclined toward the inner wall surface of the core layer 20 as the inclined surface 38A becomes closer to the distal end of the first wedge portion 38. For example, the magnetic resin 50 has a scraped corner, and the first wedge portion 38 extends into the scraped corner of the magnetic resin 50. The first wedge portion 38 covers, for example, the side surface of the magnetic resin 50 that has been scraped by formation of the first wedge portion 38. The first wedge portion 38 may be arranged over the entire circumference of the magnetic resin 50. Alternatively, the first wedge portion 38 may be arranged on part of the circumference of the magnetic resin 50.

### Structure of Pad 40A

The pad 40A is, for example, located on the lower surface of the magnetic resin 50. The pad 40A covers, for example, the lower end of the magnetic resin 50. The pad 40A covers, for example, the lower end of the magnetic resin 50 projecting downward from the lower surface 20B of the core layer 20. The pad 40A is located on the lower surface 20B of the core layer 20. The pad 40A (or wiring layer 40 including pad 40A) is an example of a second wiring layer.

The pad 40A includes, for example, a structure in which a metal foil 41A, a metal film 42A, a metal layer 43A, a metal film 44A, a metal layer 45A, a metal film 46A, and a metal layer 47A are sequentially stacked on the lower surface 20B of the core layer 20. The metal films 42A, 44A, and 46A are, for example, electroless plating films. The metal layers 43A, 45A, and 47A are, for example, electrolytic plating layers. The material of the metal foil 41A, the metal film 42A, the metal layer 43A, the metal film 44A, the metal layer 45A, the metal film 46A, and the metal layer 47A may be, for example, copper or a copper alloy. The metal film 42A is an example of a fourth metal film, and the metal layer 43A is an example of a fourth metal layer. The metal film 44A is an example of a fifth metal film, and the metal layer 45A is an example of a fifth metal layer. The metal film 46A is an example of a sixth metal film, and the metal layer 47A is an example of a sixth metal layer.

The metal foil 41A is stacked on the lower surface 20B of the core layer 20. The metal foil 41A surrounds, for example, a side surface of the lower end of the magnetic resin 50. The metal foil 41A has, for example, an annular planar shape. The metal foil 41A has, for example, a lower surface that is coplanar with the lower surface of the magnetic resin 50. In other words, the metal foil 41A has, for example, a thickness approximately equal to an amount of the magnetic resin 50 projected from the lower surface 20B of the core layer 20. The metal foil 41A may have, for example, a thickness of approximately 5 μm to 15 μm.

The metal film 42A is stacked on the lower surface of the metal foil 41A and the lower surface of the magnetic resin 50. The metal film 42A covers, for example, the entire lower surface of the metal foil 41A and the entire lower surface of the magnetic resin 50. The metal film 42A has, for example, an annular planar shape. The metal film 42A may have, for example, a thickness of approximately 1 μm to 3 μm.

The metal layer 43A is stacked on the lower surface of the metal film 42A. The metal layer 43A covers, for example, the entire lower surface of the metal film 42A. The metal layer 43A has, for example, an annular planar shape. The metal layer 43A may have, for example, a thickness of approximately 15 μm to 25 μm.

The through hole 23 extends through the metal film 42A and the metal layer 43A in the thickness-wise direction. The through hole 23 extends through the metal layer 43A, the metal film 42A, the magnetic resin 50, the metal film 32A, and the metal layer 33A in the thickness-wise direction.

The metal film 44A is stacked on the lower surface of the metal layer 43A. The metal film 44A covers the entire lower surface of the metal layer 43A. The metal film 44A is bent toward the wall surface of the through bole 23. The metal film 44A continuously covers the inner wall surface of the metal layer 43A and the inner wall surface of the metal film 42A. The metal film 44A covers, for example, the entire inner wall surface of the metal layer 43 A and the entire inner wall surface of the metal film 42A. The metal film 44A is formed continuously and integrally with the metal film 34A that forms the pad 30A. The metal film 44A may have, for example, a thickness of approximately 1 μm to 3 μm.

The metal layer 45A is stacked on the lower surface of the metal film 44A. The metal layer 45A covers the entire lower surface of the metal film 44A. The metal layer 45A is bent toward the wall surface of the through hole 23. The metal layer 45A covers the inner wall surface of the metal film 44A inside the through hole 23. The metal layer 45A covers, for example, the entire inner wall surface of the metal film 44A. The metal layer 45A is formed continuously and integrally with the metal layer 35A that forms the pad 30A. The metal layer 45A may have, for example, a thickness of approximately 15 μm to 25 μm.

The metal films 34A and 44A and the metal layers 35A and 45A arranged inside the through hole 23 extend through the core layer 20 in the thickness-wise direction. The metal films 34A and 44A and the metal layers 35A and 45A arranged inside the through hole 23 act as a through-electrode that electrically connects the pad 30A and the pad 40A. Further, in the wiring substrate 10, the magnetic resin 50 and the through-electrode, namely, the metal films 34A and 44A and the metal layers 35A and 45A arranged inside the through hole 23, may form an inductor.

The filling resin 60 fills the through hole 23 at the inner side of the metal layers 35A and 45A. The filling resin 60 has, for example, a lower surface flush with the lower surface of the metal layer 45A.

The metal film 46A is stacked on the lower surface of the metal layer 45A and the lower surface of the filling resin 60. The metal film 46A covers, for example, the entire lower surface of the metal layer 45A and the entire lower surface of the filling resin 60. The metal film 46A has, for example, a circular planar shape. The metal film 46A may have, for example, a thickness of approximately 1 μm to 3 μm.

The metal layer 47A is stacked on the lower surface of the metal film 46A. The metal layer 47A covers, for example, the entire lower surface of the metal film 46A. The metal layer 47A has, for example, a circular planar shape. The metal layer 47A may have, for example, a thickness of approximately 15 μm to 25 μm.

The pad 40A described above is, for example, greater in planar size than the through hole 23. The pad 40A is, for example, greater in planar size than the through hole 21. The pad 40A is, for example, greater in planar size than the magnetic resin 50. The pad 40A projects, for example, outward from the side surface of the magnetic resin 50.

The wiring substrate 10 includes a second wedge portion 48 extending from the pad 40A of the wiring layer 40 and wedged into the core layer 20. The second wedge portion 48 and the metal film 42A are the same metal film. The second wedge portion 48 and the metal film 42A are formed from the same material. The second wedge portion 48 and the metal film 42A are the same electroless plating film. The second wedge portion 48 is, for example, formed continuously and integrally with the metal film 42A. The second wedge portion 48 extends, for example, upward from the upper surface of the metal film 42A toward the core layer 20. The second wedge portion 48 extends, for example, through the metal foil 41A in the thickness-wise direction. The second wedge portion 48 has a distal end (here, upper end) wedged into the core layer 20. The second wedge portion 48 bas, for example, a tapered shape that narrows toward the distal end. The second wedge portion 48 has, for example, a cross-sectional shape that is a right triangle as a whole. The second wedge portion 48 includes, for example, an inclined surface 48A. The inclined surface 48A faces, for example, the side surface of the magnetic resin 50. The inclined surface 48A is, for example, in contact with the side surface of the magnetic resin 50. The inclined surface 48A is in contact with the side surface of the magnetic resin 50, for example, over the entire length of the inclined surface 48A. The inclined surface 48A is, for example, inclined toward the inner wall surface of the core layer 20 as the inclined surface 48A becomes closer to the distal end of the second wedge portion 48. For example, the magnetic resin 50 has a scraped corner, and the second wedge portion 48 extends into the scraped corner of the magnetic resin 50. The second wedge portion 48 covers, for example, the side surface of the magnetic resin 50 that has been scraped by formation of the second wedge portion 48. For example, an amount of the second wedge portion 48 wedged into the core layer 20 is greater than an amount of the first wedge portion 38 wedged into the core layer 20. In other words, the dimension of the second wedge portion 48 in a stacking direction of the wiring substrate 10 (top-bottom direction in FIG. 2) is greater than the dimension of the first wedge portion 38 in the stacking direction of the wiring substrate 10. The second wedge portion 48 may be arranged over the entire circumference of the magnetic resin 50. Alternatively, the second wedge portion 48 may be arranged on only part of the circumference of the magnetic resin 50.

### Structure of Pad 30B

The pad 30B is located on the upper surface 20A of the core layer 20. The pad 30B includes, for example, a structure in which a metal foil 31B, a metal film 32B, a metal layer 33B, a metal film 34B, a metal layer 35B, a metal film 36B, and a metal layer 37B are sequentially stacked on the upper surface 20A of the core layer 20. The metal foil 31B, the metal films 32B, 34B, and 36B, and the metal layers 33B, 35B, and 37B are, for example, formed from the same material as the metal foil 31A, the metal films 32A, 34A, and 36A, and the metal layers 33A, 35A, and 37A. The metal foil 31B, the metal films 32B, 34B, and 36B, and the metal layers 33B, 35B, and 37B are, for example, formed by the same manufacturing process as the metal foil 31A, the metal films 32A, 34A, and 36A, and the metal layers 33A, 35A, and 37A.

The metal foil 31B is stacked on the upper surface 20A of the core layer 20. The metal foil 31B has, for example, an annular planar shape. The metal film 32B is stacked on the upper surface of the metal foil 31B. The metal film 32B covers, for example, the entire upper surface of the metal foil 31B. The metal film 32B has, for example, an annular planar shape. The metal layer 33B is stacked on the upper surface of the metal film 32B. The metal layer 33B covers, for example, the entire upper surface of the metal film 32B. The metal layer 33B has, for example, an annular planar shape.

The through hole 22 extends through the core layer 20, the metal foil 31B, the metal film 32B, and the metal layer 33B in the thickness-wise direction.

The metal film 34B is stacked on the upper surface of the metal layer 33B. The metal film 34B covers the entire upper surface of the metal layer 33B. The metal film 34B is bent toward the wall surface of the through hole 22. The metal film 34B covers the wall surface of the through hole 22. The metal film 34B continuously covers the inner wall surface of the metal layer 33B, the inner wall surface of the metal film 32B, the inner wall surface of the metal foil 31B, and the inner wall surface of the core layer 20. The metal film 34B covers, for example, the entire inner wall surface of the metal layer 33B, the entire inner wall surface of the metal film 32B, the entire inner wall surface of the metal foil 31B, and the entire inner wall surface of the core layer 20.

The metal layer 35B is stacked on the upper surface of the metal film 34B. The metal layer 35B covers the entire upper surface of the metal film 34B. The metal layer 35B is bent toward the wall surface of the through hole 22. The metal layer 35B covers the inner wall surface of the metal film 34B inside the through hole 22. The metal layer 35B covers, for example, the entire inner wall surface of the metal film 34B.

Inside the through hole 22, the metal film 34B is in direct contact with the wall surface of the through hole 22, and the metal layer 35B is stacked on the metal film 34B. The filling resin 61 fills the through hole 22 at the inner side of the metal layer 35B. The filling resin 61 may be, for example, an insulating resin (e.g., epoxy-based resin) containing a filler, such as silica or the like. The filling resin 61 has, for example, an upper surface flush with the upper surface of the metal layer 35B.

The metal film 36B is stacked on the upper surface of the metal layer 35B and the upper surface of the filling resin 61. The metal film 36B covers, for example, the entire upper surface of the metal layer 35B and the entire upper surface of the filling resin 61. The metal film 36B has, for example, a circular planar shape.

The metal layer 37B is stacked on the upper surface of the metal film 36B. The metal layer 37B covers, for example, the entire upper surface of the metal film 36B. The metal layer 37B has, for example, a circular planar shape.

The pad 30B described above is, for example, greater in planar size than the filling resin 61. The pad 30B is, for example, greater in planar size than the through hole 22.

### Structure of Pad 40B

The pad 40B is located on the lower surface 20B of the core layer 20. The pad 40B includes, for example, a structure in which a metal foil 41B, a metal film 42B, a metal layer 43B, a metal film 44B, a metal layer 45B, a metal film 46B, and a metal layer 47B are sequentially stacked on the lower surface 20B of the core layer 20. The metal foil 41B, the metal films 42B, 44B, and 46B, and the metal layers 43B, 45B, and 47B are, for example, formed from the same material as the metal foil 41A, the metal films 42A, 44A, and 46A, and the metal layers 43A, 45A, and 47A. The metal foil 41B, the metal films 42B, 44B, and 46B, and the metal layers 43B, 45B, and 47B are, for example, formed from the same manufacturing process as the metal foil 41A, the metal films 42A, 44A, and 46A, and the metal layers 43A, 45A, and 47A.

The metal foil 41B is stacked on the lower surface 20B of the core layer 20. The metal foil 41B has, for example, an annular planar shape. The metal film 42B is stacked on the lower surface of the metal foil 41B. The metal film 42B covers, for example, the entire lower surface of the metal foil 41B. The metal film 42B has, for example, an annular planar shape. The metal layer 43B is stacked on the lower surface of the metal film 42B. The metal layer 43B covers, for example, the entire lower surface of the metal film 42B. The metal layer 43B has, for example, an annular planar shape.

The through hole 22 extends through the metal foil 41B, the metal film 42B, and the metal layer 43B in the thickness-wise direction. The through hole 22 extends through the metal layer 43B, the metal film 42B, the metal foil 41B, the core layer 20, the metal foil 31B, the metal film 32B, and the metal layer 33B in the thickness-wise direction.

The metal film 44B is stacked on the lower surface of the metal layer 43B. The metal film 44B covers the entire lower surface of the metal layer 43B. The metal film 44B is bent toward the wall surface of the through hole 22. The metal film 44B continuously covers the inner wall surface of the metal layer 43B, the inner wall surface of the metal film 42B, and the inner wall surface of the metal foil 41B. The metal film 44B covers, for example, the entire inner wall surface of the metal layer 43B, the entire inner wall surface of the metal film 42B, and the entire inner wall surface of the metal foil 41B. The metal film 44B is formed continuously and integrally with the metal film 34B that forms the pad 30B.

The metal layer 45B is stacked on the lower surface of the metal film 44B. The metal layer 45B covers the entire lower surface of the metal film 44B. The metal layer 45B is bent toward the wall surface of the through hole 22. The metal layer 45B covers the inner wall surface of the metal film 44B inside the through hole 22. The metal layer 45B covers, for example, the entire inner wall surface of the metal film 44B.

The metal films 34B and 44B and the metal layers 35B and 45B arranged inside the through hole 22 extend through the core layer 20 in the thickness-wise direction. The metal films 34B and 44B and the metal layers 35B and 45B arranged inside the through hole 22 act as a through-electrode that electrically connects the pad 30B and the pad 40B. The filling resin 61 fills the through hole 22 at the inner side of the metal layers 35B and 45B. The filling resin 61 has, for example, a lower surface flush with the lower surface of the metal layer 45B.

The metal films 46B are stacked on the lower surface of the metal layer 45B and the lower surface of the filling resin 61. The metal film 46B covers, for example, the entire lower surface of the metal layer 45B and the entire lower surface of the filling resin 61. The metal film 46B has, for example, a circular planar shape.

The metal layer 47B is stacked on the lower surface of the metal film 46B. The metal layer 47B covers, for example, the entire lower surface of the metal film 46B. The metal layer 47B has, for example, a circular planar shape.

The pad 40B described above is, for example, greater in planar size than the filling resin 61. The pad 40B is, for example, greater in planar size than the through hole 22.

### Overview of Wiring Structures 70 and 80

As illustrated in FIG. 1, the wiring structure 70 includes a structure in which an insulating layer 71, a wiring layer 72, an insulating layer 73, a wiring layer 74, and a solder resist layer 75 are sequentially stacked on the upper surface 20A of the core layer 20. The wiring structure 80 includes a structure in which an insulating layer 81, a wiring layer 82, an insulating layer 83, a wiring layer 84, and a solder resist layer 85 are sequentially stacked on the lower surface 20B of the core layer 20.

The material of the wiring layers 72, 74, 82, and 84 may be, for example, copper or a copper alloy. The material of the insulating layers 71, 73, 81, and 83 may be, for example, a non-photosensitive insulating resin including a thermosetting resin, such as an epoxy-based resin, a polyimide-based resin, or the like, as a main component. The insulating layers 71, 73, 81, and 83 may each contain, for example, a filler, such as silica, alumina, or the like. The material of the solder resist layers 75, and 85 may be, for example, an insulating resin including a photosensitive resin, such as a phenol-based resin, a polyimide-based resin, or the like, as a main component. The solder resist layers 75 and 85 may each contain, for example, a filler, such as silica, alumina, or the like.

### Wiring Structure 70

The insulating layer 71 is arranged on the upper surface 20A of the core layer 20 and covers the wiring layer 30. The insulating layer 71 includes through holes 71X that extend through the insulating layer 71 in the thickness-wise direction and expose parts of the upper surface of the wiring layer 30.

The wiring layer 72 is located on the upper surface of the insulating layer 71. The wiring layer 72 is formed integrally with via wirings arranged in the through holes 71X and is electrically connected to the wiring layer 30 by the via wirings.

The insulating layer 73 is arranged on the upper surface of the insulating layer 71 and covers the wiring layer 72. The insulating layer 73 includes through holes 73X that extend through the insulating layer 73 in the thickness-wise direction and expose parts of the upper surface of the wiring layer 72.

The wiring layer 74 is located on the upper surface of the insulating layer 73. The wiring layer 74 is formed integrally with via wirings arranged in the through holes 73X and is electrically connected to the wiring layer 72 by the via wirings.

The solder resist layer 75 is arranged on the upper surface of the insulating layer 73 and covers the wiring layer 74. The solder resist layer 75 includes openings 75X that extend through the solder resist layer 75 in the thickness-wise direction and expose parts of the upper surface of the wiring layer 74.

In an example, a connection terminal 76 is disposed on the wiring layer 74 that is exposed from the opening 75X. For example, the connection terminal 76 extends through the opening 75X and projects upward from the upper surface of the solder resist layer 75. The opening 75X is, for example, filled with the connection terminal 76. The connection terminal 76 may include, for example, a metal post and a bump arranged on the metal post. Although not illustrated in the drawings, the connection terminal 76 is, for example, electrically connected to an electrode of a semiconductor element mounted on the wiring substrate 10.

### Wiring Structure 80

The insulating layer 81 is arranged on the lower surface 20B of the core layer 20 and covers the wiring layer 40. The insulating layer 81 includes through holes 81X that extend through the insulating layer 81 in the thickness-wise direction and expose parts of the lower surface of the wiring layer 40.

The wiring layer 82 is located on the lower surface of the insulating layer 81. The wiring layer 82 is formed integrally with via wirings arranged in the through holes 81X and is electrically connected to the wiring layer 40 by the via wirings.

The insulating layer 83 is arranged on the lower surface of the insulating layer 81 and covers the wiring layer 82. The insulating layer 83 includes through holes 83X that extend through the insulating layer 83 in the thickness-wise direction and expose parts of the lower surface of the wiring layer 82.

The wiring layer 84 is located on the lower surface of the insulating layer 83. The wiring layer 84 is formed integrally with via wirings arranged in the through holes 83X and is electrically connected to the wiring layer 82 by the via wirings.

The solder resist layer 85 is arranged on the lower surface of the insulating layer 83 and covers the wiring layer 84. The solder resist layer 85 includes openings 85X that extend through the solder resist layer 85 in the thickness-wise direction and expose parts of the lower surface of the wiring layer 84.

The wiring substrate 10 may be used in a state flipped upside down. In FIG. 2, the wiring substrate 10 may be positioned so that the upper surface 20A of the core layer 20 faces downward and the lower surface 20B of the core layer 20 faces upward. The wiring substrate 10 may be positioned at any angle.

### Manufacturing Method of Wiring Substrate 10

A method for manufacturing the wiring substrate 10 will now be described. In particular, a method for manufacturing the core layer 20, the wiring layers 30 and 40, the magnetic resin 50, and the filling resins 60 and 61 will be described.

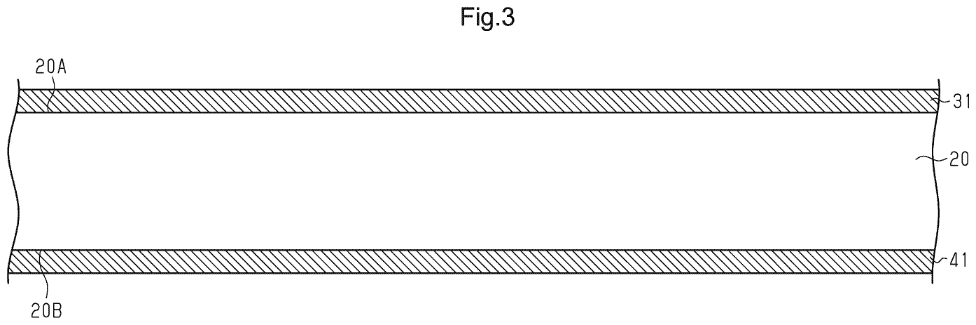

First, the step illustrated in FIG. 3 prepares a structural body including the core layer 20, a metal foil 31 stacked on the upper surface 20A of the core layer 20, and a metal foil 41 stacked on the lower surface 20B of the core layer 20. The metal foil 31 becomes the metal foils 31A and 31B (refer to FIG. 2) after being patterned by a subsequent step. In the present step, the metal foil 31 has not been patterned. The metal foil 41 becomes the metal foils 41A and 41B (refer to FIG. 2) after being patterned by a subsequent step. In the present step, the metal foil 41 has not been patterned.

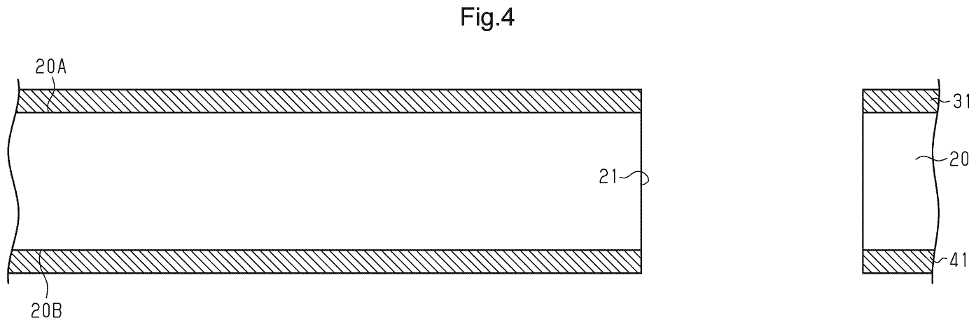

The subsequent step illustrated in FIG. 4 forms the through hole 21 extending through the metal foil 31, the core layer 20, and the metal foil 41 in a thickness-wise direction. The through hole 21 may be formed, for example, by laser drilling, mechanical drilling, or the like. Then, a desmear process may be performed to remove resin smears (resin residue) from the wall surface of the through hole 21, if necessary. In an example, the desmear process may be performed using a potassium permanganate solution.

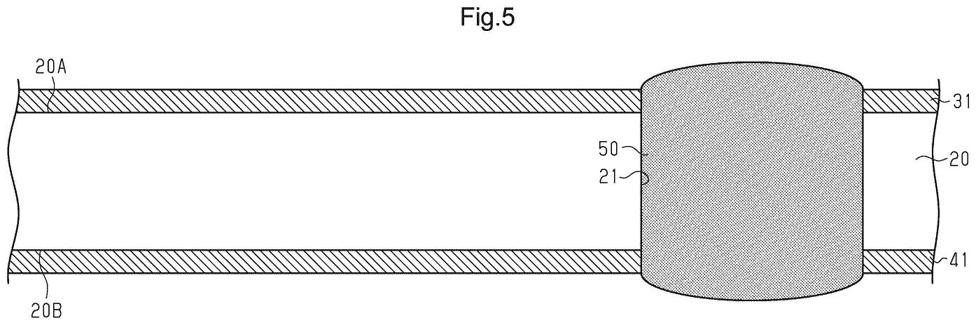

The subsequent step illustrated in FIG. 5 fills the through hole 21 with the magnetic resin 50. The magnetic resin 50 may be formed, for example, by screen printing or the like. The magnetic resin 50 projects, for example, upward from the upper surface of the metal foil 31 and downward from the lower surface of the metal foil 41.

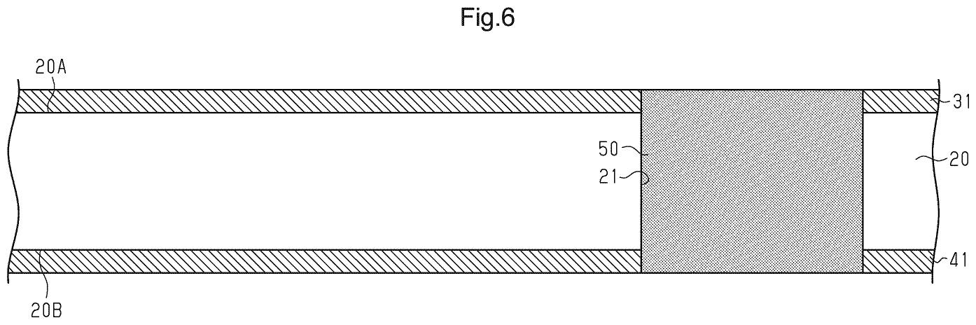

The subsequent step illustrated in FIG. 6 polishes the magnetic resin 50 projecting upward from the metal foil 31 and downward from the metal foil 41. The magnetic resin 50 may be polished by, for example, buffing, roll polishing, or the like. In the present step, the upper surface of the magnetic resin 50 becomes flush with the upper surface of the metal foil 31, and the lower surface of the magnetic resin 50 becomes flush with the lower surface of the metal foil 41.

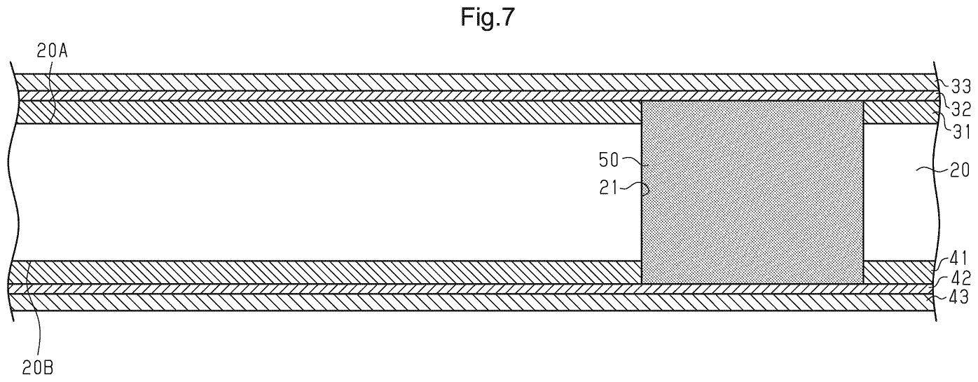

The subsequent step illustrated in FIG. 7 forms a metal film 32 that continuously covers the upper surface of the metal foil 31 and the upper surface of the magnetic resin 50. The metal film 32 may be formed, for example, by electroless plating. Then, a metal layer 33 is stacked on the upper surface of the metal film 32. The metal layer 33 may be formed, for example, by electrolytic plating that uses the metal film 32 as a power feeding layer. In the same manner, a metal film 42 is formed to continuously cover the lower surface of the metal foil 41 and the lower surface of the magnetic resin 50. The metal film 42 may be formed, for example, by electroless plating. Then, a metal layer 43 is stacked on the lower surface of the metal film 42. The metal layer 43 may be formed, for example, by electrolytic plating that uses the metal film 42 as a power feeding layer.

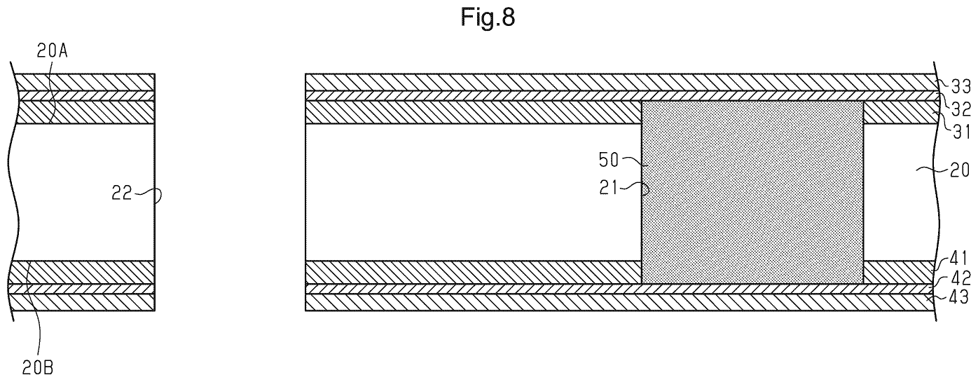

The subsequent step illustrated in FIG. 8 forms the through hole 22 extending through the metal layer 33, the metal film 32, the metal foil 31, the core layer 20, the metal foil 41, the metal film 42, and the metal layer 43 in the thickness-wise direction. The through hole 22 may be formed, for example, by laser drilling, mechanical drilling, or the like. Then, a desmear process is performed to remove resin residue from the wall surface of the through hole 22, if necessary.

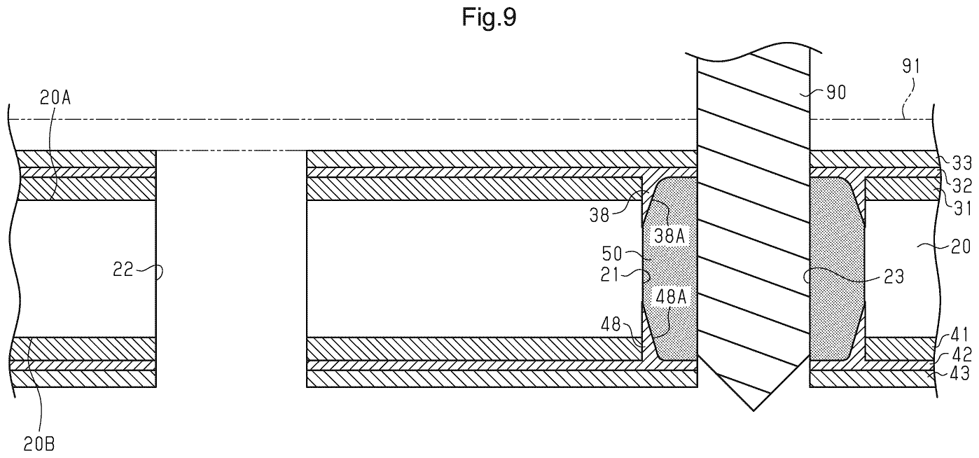

The subsequent step illustrated in FIG. 9 forms the through hole 23 extending through the metal layer 33, the metal film 32, the magnetic resin 50, the metal film 42, and the metal layer 43 in the thickness-wise direction. The through hole 23 may be formed, for example, by laser drilling, mechanical drilling, or the like. Then, the wall surface of the through hole 23 may be washed with water to remove residue of the magnetic resin 50, if necessary.

The through hole 23 of the present embodiment is formed by mechanical drilling using a drill 90. The drilling of the present step forms the first wedge portion 38 wedged into the core layer 20 by applying heat through the drill 90 to the metal film 32 so as to stretch part of the metal film 32 toward the core layer 20. Further, the drilling of the present step forms the second wedge portion 48 wedged into the core layer 20 by applying heat through the drill 90 to the metal film 42 so as to stretch part of the metal film 42 toward the core layer 20. In other words, in the drilling of the present step, the amount of heat applied through the drill 90 to the metal films 32 and 42 is adjusted so that the first wedge portion 38 and the second wedge portion 48 are formed. For example, a drilling condition is set so that a relatively large amount of heat is transferred through the drill 90 to the metal films 32 and 42. For example, a speed at which the drill 90 is depressed when forming the through hole 23 is set to be higher than a speed at which the drill 90 is depressed when forming the through hole 21. For example, a speed at which the drill 90 is depressed when forming the through hole 21 is set to 3 m/min, and a speed at which the drill 90 is depressed when forming the through hole 23 is set to 5 m/min. Further, for example, a speed at which the drill 90 is extracted when forming the through hole 23 is set to be higher than a speed at which the drill 90 is extracted when forming the through hole 21.

In this manner, the drill 90 is depressed and extracted at a relatively high speed so that a relatively large amount of heat is applied through the drill 90 to the metal films 32 and 42. This stretches the metal films 32 and 42, such that the metal films 32 and 42 extend toward the core layer 20 through gaps formed between the metal foils 31 and 41 and the magnetic resin 50. Further, the metal films 32 and 42 extend toward the core layer 20 while scraping the corners of the magnetic resin 50. This forms the first wedge portion 38 and the second wedge portion 48 wedged into the core layer 20. The first wedge portion 38 and the second wedge portion 48 cover the side surface of the scraped magnetic resin 50 in a state in which the first wedge portion 38 and the second wedge portion 48 are in contact with the side surface. The first wedge portion 38 and the second wedge portion 48 improve adhesion between the metal films 32 and 42, the core layer 20, and the magnetic resin 50. The magnetic resin 50 has a smaller outer diameter at a portion where the first wedge portion 38 and the second wedge portion 48 are formed than a portion where the first wedge portion 38 and the second wedge portion 48 are not formed.

When forming the through hole 23 by depressing the drill 90 from above the metal layer 33, a lubricant 91, for example, is applied to the metal layer 33. The lubricant 91 reduces the amount of heat generated by the drill 90. Accordingly, a smaller amount of heat is applied from the drill 90 to the metal film 32 that is located close to the lubricant 91, than to the metal film 42 that is located far away from the lubricant 91. In other words, a greater amount of heat is applied through the drill 90 to the metal film 42 than to the metal film 32. As a result, the amount of the second wedge portion 48 wedged into the core layer 20 is greater than the amount of the first wedge portion 38 wedged into the core layer 20.

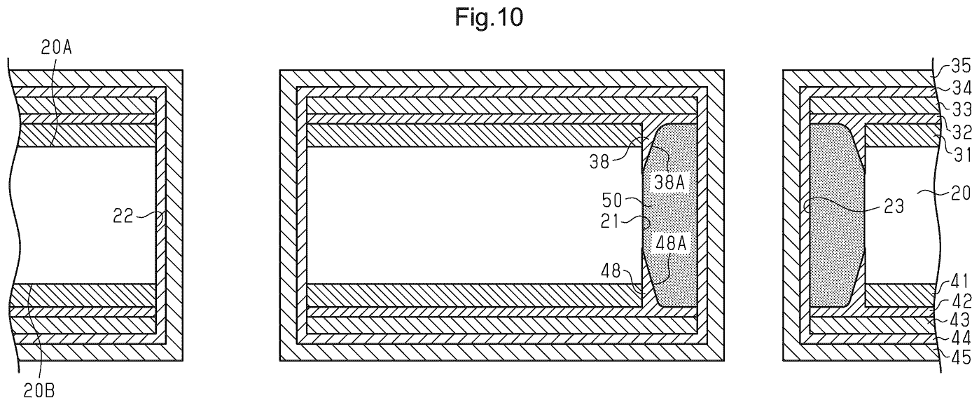

The subsequent step illustrated in FIG. 10 forms metal films 34 and 44 that cover the upper surface of the metal layer 33, the wall surface of the through hole 22, the wall surface of the through hole 23, and the lower surface of the metal layer 43. The metal films 34 and 44 may be formed, for example, by electroless plating. The metal film 34 and the metal film 44 are formed continuously and integrally with each other as a single layer. Then, metal layers 35 and 45 are stacked on the metal films 34 and 44. The metal layers 35 and 45 may be formed, for example, by electrolytic plating that uses the metal films 34 and 44 as a power feeding layer. The metal layer 35 and the metal layer 45 are formed continuously and integrally with each other as a single layer.

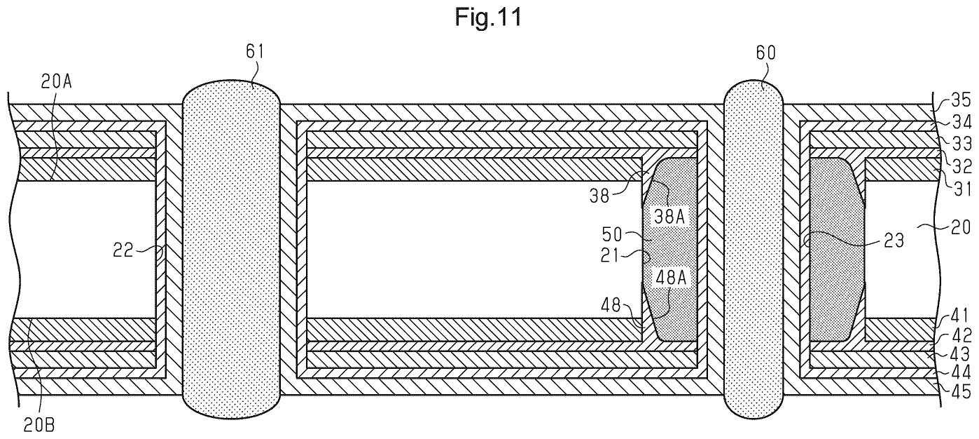

The subsequent step illustrated in FIG. 11 fills the through hole 23 with the filling resin 60 at the inner side of the metal layers 35 and 45, and fills the through hole 22 with the filling resin 61 at the inner side of the metal layers 35 and 45. The filling resins 60 and 61 may be formed, for example, by screen printing or the like. The filling resins 60 and 61 project, for example, upward from the upper surface of the metal layer 35 and downward from the lower surface of the metal layer 45.

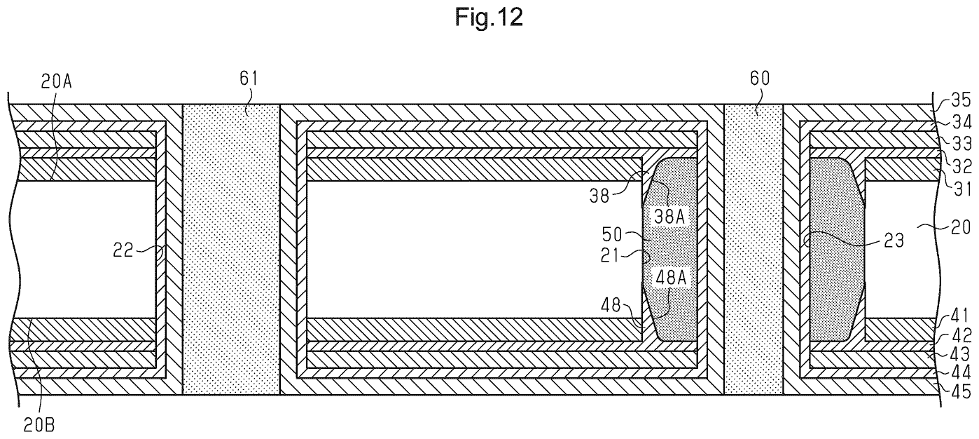

The subsequent step illustrated in FIG. 12 polishes the filling resins 60 and 61 projecting upward from the metal layer 35 and downward from the metal layer 45. The filling resins 60 and 61 may be polished, for example, by buffing, roll polishing, or the like. In the present step, the upper surfaces of the filling resins 60 and 61 become flush with the upper surface of the metal layer 35, and the lower surfaces of the filling resins 60 and 61 become flush with the lower surface of the metal layer 45.

Then, a desmear process may be performed to remove resin residue from the upper surfaces of the filling resins 60 and 61, the lower surfaces of the filling resins 60 and 61, the upper surface of the metal layer 35, and the lower surface of the metal layer 45, if necessary.

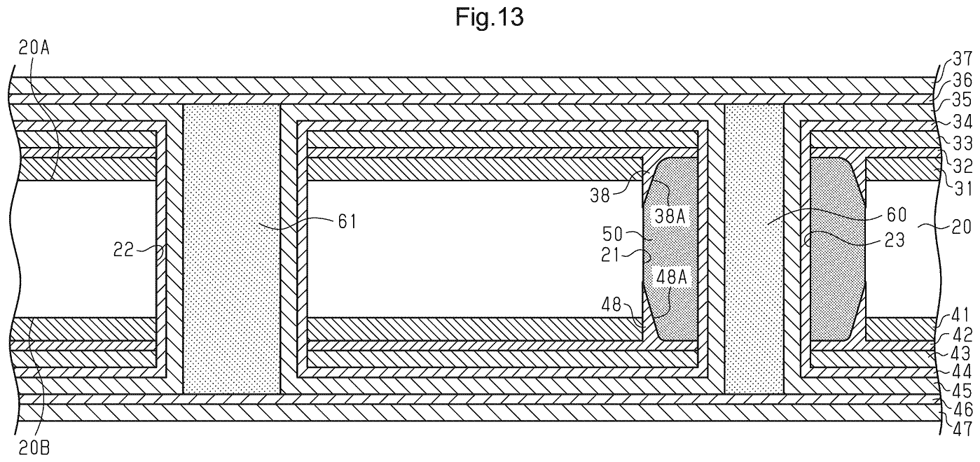

The subsequent step illustrated in FIG. 13 forms a metal film 36 that continuously covers the upper surface of the metal layer 35 and the upper surfaces of the filling resins 60 and 61. The metal film 36 may be formed, for example, by electroless plating. Then, a metal layer 37 is stacked on the upper surface of the metal film 36. The metal layer 37 may be formed, for example, by electrolytic plating that uses the metal film 36 as a power feeding layer. In the same manner, the present step forms a metal film 46 that continuously covers the lower surface of the metal layer 45 and the lower surfaces of the filling resins 60 and 61. The metal film 46 may be formed, for example, by electroless plating. Then, a metal layer 47 is stacked on the lower surface of the metal film 46. The metal layer 47 may be formed, for example, by electrolytic plating that uses the metal film 46 as a power feeding layer.

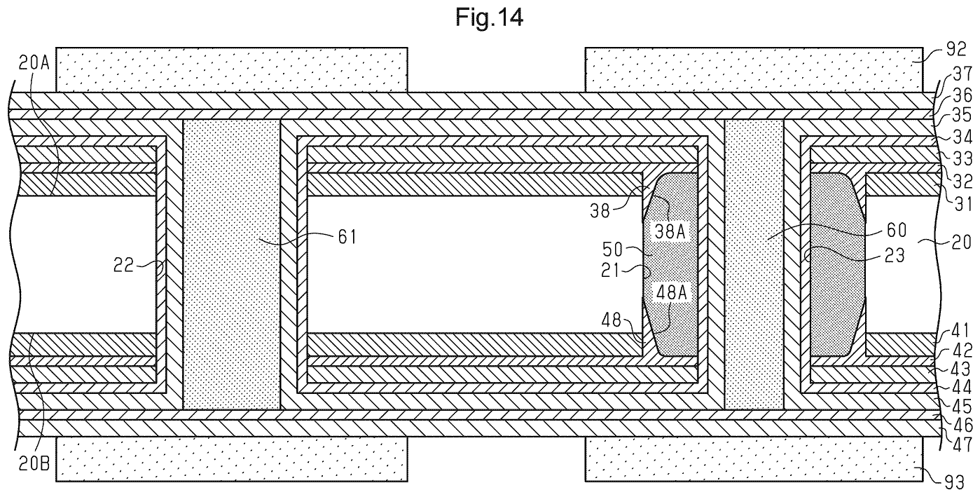

The subsequent step illustrated in FIG. 14 forms a resist layer 92 on the upper surface of the metal layer 37 to cover regions where the wiring layer 30 (refer to FIG. 2), which includes the pads 30A and 30B, is to be formed. Further, the present step forms a resist layer 93 on the lower surface of the metal layer 47 to cover regions where the wiring layer 40 (refer to FIG. 2), which includes the pads 40A and 40B, is to be formed. The material of the resist layers 92 and 93 is not particularly limited as long as the material has a desired resolution and is resistant to etching.

In an example, the resist layers 92 and 93 arranged at the regions where the pads 30A and 40A are to be formed are greater in planar size than the magnetic resin 50, and overlap the magnetic resin 50 in plan view. In an example, the resist layers 92 and 93 arranged at the regions where the pads 30B and 40B are to be formed are greater in planar size than the through hole 22, and overlap the through hole 22 in plan view.

Then, etching is performed using the resist layer 92 as an etching mask to remove the metal foil 31, the metal film 32, the metal layer 33, the metal film 34, the metal layer 35, the metal film 36, and the metal layer 37. Further, etching is performed using the resist layer 93 as an etching mask to remove the metal foil 41, the metal film 42, the metal layer 43, the metal film 44, the metal layer 45, the metal film 46, and the metal layer 47. When copper or a copper alloy is used as the material of the metal foils 31 and 41, the metal films 32, 34, 36, 42, 44, and 46, and the metal layers 33, 35, 37, 43, 45, and 47, for example, an etchant may be a ferric chloride aqueous solution, a cupric chloride aqueous solution, or the like.

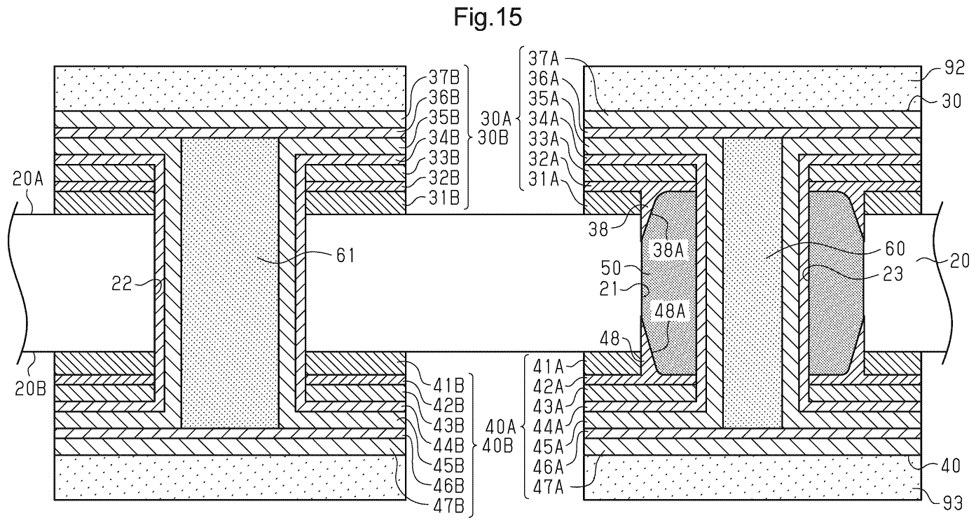

As illustrated in FIG. 15, the present step forms the pad 30A, in which the metal foil 31A, the metal film 32A, the metal layer 33A, the metal film 34A, the metal layer 35A, the metal film 36A, and the metal layer 37A are sequentially stacked on the upper surface 20A of the core layer 20. Further, the present step forms the pad 30B, in which the metal foil 31B, the metal film 32B, the metal layer 33B, the metal film 34B, the metal layer 35B, the metal film 36B, and the metal layer 37B are sequentially stacked on the upper surface 20A of the core layer 20. Consequently, the wiring layer 30 including the pads 30A and 30B is formed on the upper surface 20A of the core layer 20. In the same manner, the present step forms the pad 40A, in which the metal foil 41A, the metal film 42A, the metal layer 43A, the metal film 44A, the metal layer 45A, the metal film 46A, and the metal layer 47A are sequentially stacked on the lower surface 20B of the core layer 20. Further, the present step forms the pad 40B, in which the metal foil 41B, the metal film 42B, the metal layer 43B, the metal film 44B, the metal layer 45B, the metal film 46B, and the metal layer 47B are sequentially stacked on the lower surface 20B of the core layer 20. Consequently, the wiring layer 40 including the pads 40A and 40B are formed on the lower surface 20B of the core layer 20.

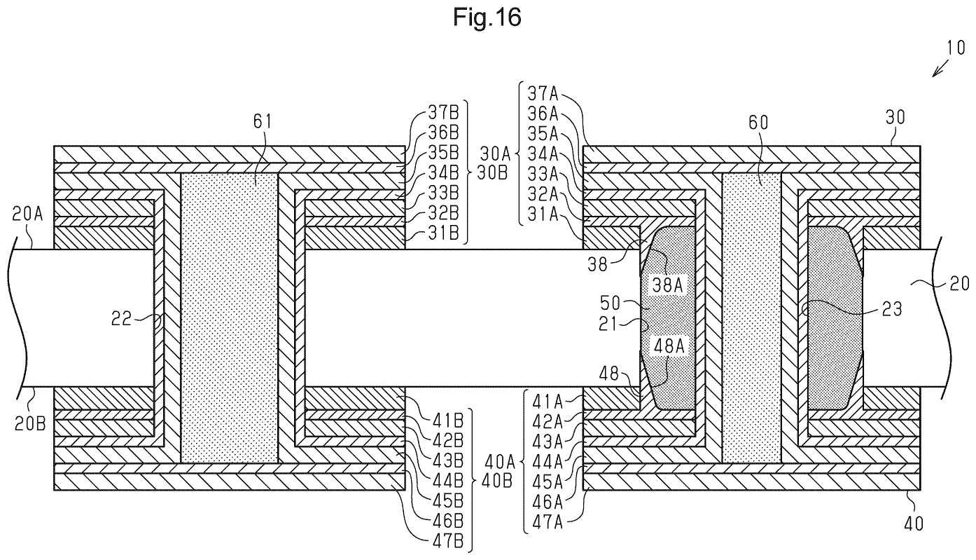

The subsequent step illustrated in FIG. 16 removes the resist layers 92 and 93 illustrated in FIG. 15 using an alkaline stripping solution (e.g., organic amine-based stripping solution, caustic soda, acetone, ethanol, or the like). If adhesion of the metal films 32A and 42A to the core layer 20 and the magnetic resin 50 is poor, the pads 30A and 40A may delaminate from the magnetic resin 50 and the core layer 20 during the manufacturing process, such as the present step. Accordingly, in the present embodiment, the first wedge portion 38 and the second wedge portion 48 are formed to improve the adhesion of the metal films 32A and 42A to the core layer 20 and the magnetic resin 50. This appropriately avoids delamination of the pads 30A and 40A from the core layer 20 and the magnetic resin 50.

### Advantages

### The Above Embodiment Has the Following Advantages

(1) The first wedge portion 38 extends from the wiring layer 30 and is wedged into the core layer 20. The first wedge portion 38 is formed continuously and integrally with the metal film 32A. The first wedge portion 38 extends from the metal film 32A toward the core layer 20. With this structure, the first wedge portion 38 wedged into the core layer 20 improves adhesion between the metal film 32A, which is formed continuously and integrally with the first wedge portion 38, and the core layer 20. This appropriately avoids delamination of the pad 30A from the core layer 20 and the magnetic resin 50.

(2) The first wedge portion 38 is continuous and integral with the metal film 32A during and after the manufacture of the wiring substrate 10. Therefore, the adhesion between the metal film 32A and the core layer 20 is satisfactory during and after the manufacture of the wiring substrate 10. This appropriately avoids delamination of the pad 30A from the core layer 20 and the magnetic resin 50 during and after the manufacture of the wiring substrate 10.

(3) The first wedge portion 38 extends in the thickness-wise direction through the metal foil 31A, which is stacked on the upper surface 20A of the core layer 20. With this structure, an area of contact between the first wedge portion 38 and the metal foil 31A is increased, and an area of contact between the first wedge portion 38 and the magnetic resin 50 is increased. This improves adhesion between the first wedge portion 38 and the metal foil 31A, as well as adhesion between the first wedge portion 38 and the magnetic resin 50.

(4) The first wedge portion 38 has a cross-sectional shape that includes the inclined surface 38A facing the side surface of the magnetic resin 50. The inclined surface 38A increases an area of contact between the first wedge portion 38 and the magnetic resin 50. This improves adhesion between the first wedge portion 38 and the magnetic resin 50.

(5) The second wedge portion 48 extends from the wiring layer 40 and is wedged into the core layer 20. The second wedge portion 48 is formed continuously and integrally with the metal film 42A. The second wedge portion 48 extends from the metal film 42A toward the core layer 20. With this structure, the second wedge portion 48 wedged into the core layer 20 improves adhesion between the metal film 42A, which is formed continuously and integrally with the second wedge portion 48, and the core layer 20. This appropriately avoids delamination of the pad 40A from the core layer 20 and the magnetic resin 50.

(6) The dimension of the second wedge portion 48 in the stacking direction of the wiring substrate 10 is greater than the dimension of the first wedge portion 38 in the stacking direction of the wiring substrate 10. This structure further improves adhesion between the second wedge portion 48 and the core layer 20. As a result, delamination of the pad 40A from the core layer 20 and the magnetic resin 50 is further avoided.

### Modified Examples

The above embodiment may be modified as described below. The above embodiment and the following modifications may be combined if the combined modifications remain technically consistent with each other.

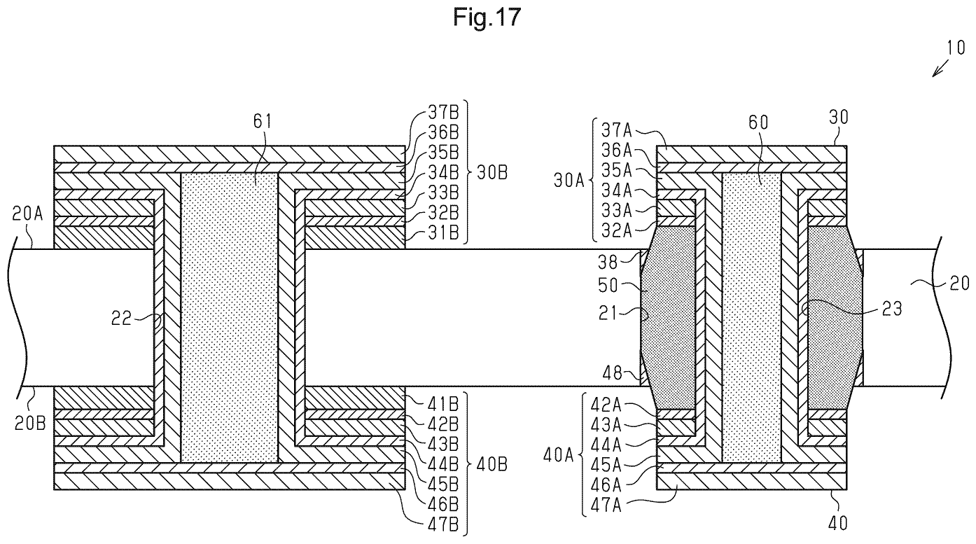

As illustrated in FIG. 17, the pad 30A may be arranged only on the upper surface of the magnetic resin 50, instead of both the upper surface 20A of the core layer 20 and the upper surface of the magnetic resin 50. In this case, the pad 30A includes a structure in which the metal film 32A, the metal layer 33A, the metal film 34A, the metal layer 35A, the metal film 36A, and the metal layer 37A are sequentially stacked on the upper surface of the magnetic resin 50. The pad 30A of the present modified example is smaller in planar size than the magnetic resin 50. In other words, the magnetic resin 50 of the present modified example projects outward from the side surface of the pad 30A. The first wedge portion 38 of the present modified example is separated from the metal film 32A. Nonetheless, the first wedge portion 38 and the metal film 32A are the same metal film. Therefore, the first wedge portion 38 and the metal film 32A are the same electroless plating film. The first wedge portion 38 and the metal film 32A are formed from the same material. In other words, the metal film 32A of the present modified example includes a metal film body portion, which is located on the upper surface of the magnetic resin 50, and the first wedge portion 38, which is located away from the metal film body portion on the side surface of the magnetic resin 50 and formed from a metal material that is the same as that of the metal film body portion.

In an example, the resist layer 92 formed in the step illustrated in FIG. 14 is changed to have a smaller planar size than the magnetic resin 50, and then the pad 30A of the present modified example is formed by etching that uses the resist layer 92 as a mask. This etching separates the first wedge portion 38 from the metal film 32A. In other words, the first wedge portion 38 is continuous and integral with the metal film 32A until the etching. This improves adhesion of the metal film 32A and the first wedge portion 38 to the core layer 20 during the manufacture of the wiring substrate 10, thereby appropriately avoiding delamination of the pad 30A from the core layer 20 and the magnetic resin 50. The above-described etching removes part of the first wedge portion 38, such that the side surface of the magnetic resin 50 having the scraped corner is exposed from the first wedge portion 38.

As illustrated in FIG. 17, the pad 40A may be arranged only on the lower surface of the magnetic resin 50, instead of both the lower surface 20B of the core layer 20 and the lower surface of the magnetic resin 50. In this case, the pad 40A includes a structure in which the metal film 42A, the metal layer 43A, the metal film 44A, the metal layer 45A, the metal film 46A, and the metal layer 47A are sequentially stacked on the lower surface of the magnetic resin 50. The pad 40A of the present modified example is smaller in planar size than the magnetic resin 50. In other words, the magnetic resin 50 of the present modified example projects outward from the side surface of the pad 40A. The second wedge portion 48 of the present modified example is separated from the metal film 42A. Nonetheless, the second wedge portion 48 and the metal film 42A are the same metal film. Therefore, the second wedge portion 48 and the metal film 42A are the same electroless plating film. The second wedge portion 48 and the metal film 42A are formed from the same material. In other words, the metal film 42A of the present modified example includes a metal film body portion, which is located on the lower surface of the magnetic resin 50, and the second wedge portion 48, which is located away from the metal film body portion of the metal film 42A on the side surface of the magnetic resin 50 and formed from a metal material that is the same as that of the metal film body portion of the metal film 42A.

In an example, the resist layer 93 formed in the step illustrated in FIG. 14 is changed to have a smaller planar size than the magnetic resin 50, and then the pad 40A of the present modified example is formed by etching that uses the resist layer 93 as a mask. This etching separates the second wedge portion 48 from the metal film 42A. In other words, the second wedge portion 48 is continuous and integral with the metal film 42A until the etching. This improves adhesion of the metal film 42A and the second wedge portion 48 to the core layer 20 during the manufacture of the wiring substrate 10, thereby appropriately avoiding delamination of the pad 40A from the core layer 20 and the magnetic resin 50. The above-described etching removes part of the second wedge portion 48, such that the side surface of the magnetic resin 50 having the scraped corner is exposed from the second wedge portion 48.

In the above embodiment, the second wedge portion 48 is set to have a greater dimension in the stacking direction of the wiring substrate 10 than the first wedge portion 38. However, there is no limitation to such a structure. For example, the second wedge portion 48 may be set to have the same dimension in the stacking direction of the wiring substrate 10 as the first wedge portion 38. For example, the second wedge portion 48 may be set to have a smaller dimension in the stacking direction of the wiring substrate 10 than the first wedge portion 38.

The shape of the first wedge portion 38 in the above embodiment may be changed in any manner.

In the above embodiment, the first wedge portion 38 has a cross-sectional shape including the inclined surface 38A. However, the cross-sectional shape of the first wedge portion 38 does not have to include the inclined surface 38A.

The shape of the second wedge portion 48 in the above embodiment may be changed in any manner.

In the above embodiment, the second wedge portion 48 has a cross-sectional shape including the inclined surface 48A. However, the cross-sectional shape of the second wedge portion 48 does not have to include the inclined surface 48A. The second wedge portion 48 of the above embodiment may be omitted.

The metal foils 31A and 41A of the above embodiment may be omitted. In this case, the upper surface of the magnetic resin 50 may be coplanar with the upper surface 20A of the core layer 20. Further, the lower surface of the magnetic resin 50 may be coplanar with the lower surface 20B of the core layer 20.

There may be any number of magnetic resins 50 in the wiring substrate 10. The wiring substrate 10 may include two or more magnetic resins 50.

In the above embodiment, the through hole 23 is filled with the filling resin 60 at the inner side of the metal layers 35A and 45A. However, for example, the filling resin 60 may be omitted. In this case, the through hole 23 may be filled with the metal layers 35A and 45A at the inner side of the metal films 34A and 44A. In this case, the metal films 36A and 46A and the metal layers 37A and 47A may be omitted.

In the above embodiment, the through hole 22 is filled with the filling resin 61 at the inner side of the metal layers 35B and 45B. However, the filling resin 61 may be omitted, for example. In this case, the through hole 22 may be filled with the metal layers 35B and 45B at the inner side of the metal films 34B and 44B. In this case, the metal films 36B and 46B and the metal layers 37B and 47B may be omitted.

The connection terminals 76 of the above embodiment may be omitted.

The solder resist layers 75 and 85 of the above embodiment may be omitted.

The layout and the numbers of the insulating layers 71 and 73 and the wiring layers 72 and 74 in the wiring structure 70 of the above embodiment may be changed.

The wiring structure 70 of the above embodiment may be omitted.

The layout and the numbers of the insulating layers 81 and 83 and the wiring layers 82 and 84 in the wiring structure 80 of the above embodiment may be changed.

The wiring structure 80 of the above embodiment may be omitted.

### Clauses

This disclosure further encompasses the following embodiments.

1. A wiring substrate, including:
a core layer including a first through hole;
a magnetic resin filling the first through hole;
a first wiring layer arranged on an upper surface of the magnetic resin; and a first wedge portion wedged into the core layer, the first wedge portion extending from an upper surface of the core layer into the first through hole and being sandwiched between the core layer and the magnetic resin, in which:
the first wiring layer includes a structure in which a first metal film, a first metal layer, a second metal film, and a second metal layer are sequentially stacked on the upper surface of the magnetic resin; and
the first metal film includes
   a metal film body portion located on the upper surface of the magnetic resin, and
   the first wedge portion located away from the metal film body portion on a side surface of the magnetic resin and formed from a metal material that is the same as that of the metal film body portion.

2. A method for manufacturing a wiring substrate, the method including:
preparing a core layer;
forming a first through hole that extends through the core layer in a thickness-wise direction;
forming a magnetic resin that fills the first through hole;
forming, by electroless plating, a first metal film that covers an upper surface of the magnetic resin;
forming, by electrolytic plating, a first metal layer that covers an upper surface of the first metal film;
forming, by drilling using a drill, a second through hole that extends through the first metal layer, the first metal film, and the magnetic resin in the thickness-wise direction;
forming a first wedge portion wedged into the core layer by applying heat through the drill to the first metal film so as to stretch part of the first metal film toward the core layer;
forming, by electroless plating, a second metal film that covers an upper surface of the first metal layer and a wall surface of the second through hole;
forming, by electrolytic plating, a second metal layer that covers an upper surface of the second metal film and an inner wall surface of the second metal film; and
forming a first wiring layer on the upper surface of the magnetic resin by patterning the first metal film, the first metal layer, the second metal film, and the second metal layer,
in which the forming the first wedge portion includes adjusting an amount of heat applied through the drill to the first metal film so that the first wedge portion is formed.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a core layer including a first through hole;
a magnetic resin filling the first through hole;
a first wiring layer arranged on an upper surface of the magnetic resin; and
a first wedge portion extending from the first wiring layer and wedged into the core layer, wherein:
the first wiring layer includes a structure in which a first metal film, a first metal layer, a second metal film, and a second metal layer are sequentially stacked on the upper surface of the magnetic resin;
the first wedge portion is formed continuously and integrally with the first metal film; and
the first wedge portion extends from the first metal film toward the core layer.

2. The wiring substrate according to claim 1, wherein
the first metal film is in contact with the upper surface of the magnetic resin, and
the first wedge portion is sandwiched between an inner wall surface of the core layer, which defines a wall surface of the first through hole, and a side surface of the magnetic resin in a state in which the first wedge portion is in contact with the inner wall surface of the core layer and the side surface of the magnetic resin.

3. The wiring substrate according to claim 1, further comprising:
a second through hole extending through the first metal layer, the first metal film, and the magnetic resin in a thickness-wise direction,
wherein the second metal film continuously covers an upper surface of the first metal layer, an inner wall surface of the first metal layer, an inner wall surface of the first metal film, and an inner wall surface of the magnetic resin.

4. The wiring substrate according to claim 3, further comprising:
a filling resin filling the second through hole,
wherein the first wiring layer further includes a structure in which a third metal film and a third metal layer are sequentially stacked on an upper surface of the second metal layer and an upper surface of the filling resin.

5. The wiring substrate according to claim 1, further comprising:
the first wiring layer further includes a metal foil arranged on an upper surface of the core layer, wherein
the first metal film covers the upper surface of the magnetic resin and an upper surface of the metal foil, and
the first wedge portion extends through the metal foil in a thickness-wise direction.

6. The wiring substrate according to claim 1, wherein
the first wedge portion has a distal end wedged into the core layer,
the first wedge portion has a cross-sectional shape that includes an inclined surface facing a side surface of the magnetic resin, and
the inclined surface is inclined toward an inner wall surface of the core layer as the inclined surface becomes closer to the distal end of the first wedge portion.

7. The wiring substrate according to claim 1, further comprising:
a second wiring layer arranged on a lower surface of the magnetic resin; and
a second wedge portion extending from the second wiring layer and wedged into the core layer, wherein:
the second wiring layer includes a structure in which a fourth metal film, a fourth metal layer, a fifth metal film, and a fifth metal layer are sequentially stacked on the lower surface of the magnetic resin;
the second wedge portion is formed continuously and integrally with the fourth metal film; and
the second wedge portion extends from the fourth metal film toward the core layer.

8. The wiring substrate according to claim 7, wherein
the fourth metal film is in contact with the lower surface of the magnetic resin, and
the second wedge portion is sandwiched between an inner wall surface of the core layer, which defines a wall surface of the first through hole, and a side surface of the magnetic resin in a state in which the first wedge portion is in contact with the inner wall surface of the core layer and the side surface of the magnetic resin.

9. The wiring substrate according to claim 7, wherein a dimension of the second wedge portion in a stacking direction of the wiring substrate is greater than a dimension of the first wedge portion in the stacking direction.

10. The wiring substrate according to claim 7, further comprising:
a second through hole extending through the first metal layer, the first metal film, the magnetic resin, the fourth metal film, and the fourth metal layer in a thickness-wise direction, wherein:
the second metal film continuously covers an upper surface of the first metal layer, an inner wall surface of the first metal layer, an inner wall surface of the first metal film, and an inner wall surface of the magnetic resin; and
the fifth metal film continuously covers a lower surface of the fourth metal layer, an inner wall surface of the fourth metal layer, and an inner wall surface of the fourth metal film, and is formed continuously and integrally with the second metal film.

11. The wiring substrate according to claim 10, further comprising:
a filling resin filling the second through hole, wherein:
the first wiring layer further includes a structure in which a third metal film and a third metal layer are sequentially stacked on an upper surface of the second metal layer and an upper surface of the filling resin; and
the second wiring layer further includes a structure in which a sixth metal film and a sixth metal layer are sequentially stacked on a lower surface of the fifth metal layer and a lower surface of the filling resin.
